(19) United States
(12) Patent Application Publication
(10) Pub. No.: US 2025/0201699 A1
(43) Pub. Date: Jun. 19, 2025

(54) REPLACEMENT FULLY ALIGNED VIA AND METAL LINE

(71) Applicant: International Business Machines Corporation, Armonk, NY (US)

(72) Inventors: Ruilong Xie, Niskayuna, NY (US); Lawrence A. Clevenger, Saratoga Springs, NY (US); Brent A. Anderson, Jericho, VT (US); Albert M. Chu, Nashua, NH (US); Nicholas Anthony Lanzillo, Wynantskill, NY (US); Reinaldo Vega, Mahopac, NY (US)

(21) Appl. No.: 18/543,469

(22) Filed: Dec. 18, 2023

(51) Int. Cl. H01L 23/522; H01L 21/3213; H01L 21/768

(52) U.S. Cl. CPC H01L 23/5226; H01L 21/32139; H01L 21/76837; H01L 21/76877; H01L 21/76886

(57) ABSTRACT

A semiconductor interconnect structure and formation thereof. The semiconductor interconnect structure includes a lower level metal line extending along a first direction. The semicondutor interconnect structure further includes an upper level metal line extending along a second direction, where the upper level metal line includes a first portion and a second portion. The semiconductor interconnect structure further includes a via formed on top of the lower level metal line and interconnecting the lower level metal line to the upper level metal line. The via is self-aligned to the lower level metal line along the second direction and self-aligned to the upper level metal line along the first direction.

### BACKGROUND

The present disclosure generally relates to fabrication methods and structures for semiconductor devices, and more specifically, to fabricating a semicondutor interconnect structure having a via that is fully aligned to both a lower level metal line (Mx-1) and an upper level metal line (Mx).

For an integrated circuit (IC) device to be functional, multi-level or multilayered interconnection schemes such as, for example, metal wiring formed by single damascene processes, dual damascene processes, subtractive patterning (i.e., subtractive etch processes), and combinations thereof, are fabricated in the back-end-of-the-line (BEOL) of the device to connect the circuit elements distributed in the front-end-of-the-line (FEOL) of the device. Connections between the metal lines of the different interconnect levels, called vias, allow signals and power to be transmitted between one level to the next.

### SUMMARY

According to one embodiment of the present invention, a semiconductor interconnect structure is provided. The semiconductor interconnect structure includes: a lower level metal line extending along a first direction, an upper level metal line extending along a second direction, where the upper level metal line includes a first portion and a second portion, and a via formed on top of the lower level metal line that interconnects the lower level metal line to the upper level metal line. The via is self-aligned to the lower level metal line along the second direction and self-aligned to the upper level metal line along the first direction.

According to another embodiment of the present invention, a method of forming a semiconductor interconnect structure is provided. The method includes forming a first hard mask on top of a first metal layer. The method further includes etching, using the first hard mask, the first metal layer to form a lower level metal line extending along a first direction. The method further includes forming a first insulating layer, such that a top surface of the first insulating layer is coplanar with a top surface of the first hard mask. The method further includes forming a second metal layer and a second hard mask on top of the second metal layer. The method further includes etching, using the second hard mask, the second conductive metal layer to form an upper level metal line extending along a second direction. The method further includes forming a second insulating layer, such that a top surface of the second insulating layer is coplanar with a top surface of the second hard mask. The method further includes forming a soft mask having a first opening that exposes a portion of the second hard mask located on top of the upper level metal line. The method further includes selectively etching the exposed portion of the second hard mask to form a second opening that exposes a portion of the upper level metal line, where the second opening is self-aligned to the upper level metal line along the first direction. The method further includes selectively etching the exposed portion of the upper level metal line to form a trench opening in the upper metal line that exposes a portion of the first hard mask located on top of the lower level metal line. The method further includes selectively etching the exposed portion of the first hard mask to form a via opening that exposes a portion of the lower level metal line, where the via opening is self-aligned to the lower level metal line along the second direction. The method further includes filling the via opening and the trench opening formed within the upper level metal line with a conductive metal material.

### BRIEF DESCRIPTION OF THE SEVERAL VIEWS OF THE DRAWINGS

FIG. 1 illustrates a simple diagram of a top view of a semiconductor structure, generally designated 10, in accordance with at least one embodiment of the present invention.

FIGS. 2A, 2B illustrate cross-sectional views of an initial semiconductor structure, generally designated 100, in accordance with at least one embodiment of the present invention.

FIGS. 3A, 3B illustrate cross-sectional views of semiconductor structure 100 depicted in FIGS. 2A, 2B after performing subsequent processing steps, generally designated 200, in accordance with at least one embodiment of the present invention.

FIGS. 4A, 4B illustrate cross-sectional views of semiconductor structure 200 depicted in FIGS. 3A, 3B after performing subsequent processing steps, generally designated 300, in accordance with at least one embodiment of the present invention.

FIGS. 5A, 5B illustrate cross-sectional views of semiconductor structure 300 depicted in FIGS. 4A, 4B after performing subsequent processing steps, generally designated 400, in accordance with at least one embodiment of the present invention.

FIGS. 6A, 6B illustrate cross-sectional views of semiconductor structure 400 depicted in FIGS. 5A, 5B after performing subsequent processing steps, generally designated 500, in accordance with at least one embodiment of the present invention.

FIGS. 7A, 7B illustrate cross-sectional views of semiconductor structure 500 depicted in FIGS. 6A, 7B after performing subsequent processing steps, generally designated 600, in accordance with at least one embodiment of the present invention.

FIGS. 8A, 8B illustrate cross-sectional views of semiconductor structure 600 depicted in FIGS. 7A, 7B after performing subsequent processing steps, generally designated 700, in accordance with at least one embodiment of the present invention.

FIGS. 9A, 9B illustrate cross-sectional views of semiconductor structure 700 depicted in FIGS. 8A, 8B after performing subsequent processing steps, generally designated 800, in accordance with at least one embodiment of the present invention.

FIGS. 10A, 10B illustrate cross-sectional views of semiconductor structure 800 depicted in FIGS. 9A, 9B after performing subsequent processing steps, generally designated 900, in accordance with at least one embodiment of the present invention.

FIGS. 11A, 10B illustrate cross-sectional views of semiconductor structure 900 depicted in FIGS. 10A, 10B after performing subsequent processing steps, generally designated 1000, in accordance with at least one embodiment of the present invention.

### DETAILED DESCRIPTION

As integrated circuits (ICs) continue to move to smaller technology nodes, the ability to maintain and/or increase signal density to meet performance demands becomes increasingly challenging, especially when forming the lower via and metal line levels of the BEOL. Traditionally, the via levels are one of the most challenging to print with a high process latitude. As the size of the interconnects decrease, overlay errors and edge placement errors (EPEs) tend to become more prevalent. An overlay error results from misalignment during the lithography process as the mask invariably may not be perfectly aligned to the underlying structure. In turn, these overlay errors result in edge placement errors. An edge placement error is the misalignment or variation of placement of one feature (e.g., via) with respect to another feature (e.g., metal line). Edge placement errors increase via resistance and lead to potential shorting to neighboring metal lines, which ultimately results in device reliability and performance issues.

Embodiments of the present invention provide for improved semiconductor interconnect structures and methods of forming the same that eliminate overlay errors and edge placement errors when forming a via on top of a lower level metal line (Mx-1). In turn, the improved semiconductor interconnect structures and methods of forming the same result in a via formed on top of a lower level metal line (Mx-1) that is fully aligned to both the lower level metal line (Mx-1) and an upper level metal line (Mx) formed on top of the via, thereby ultimately eliminating any reliability or performance issues caused by edge placement errors.

According to one embodiment of the present invention, a semiconductor interconnect structure is provided. The semiconductor interconnect structure includes: a lower level metal line extending along a first direction, an upper level metal line extending along a second direction, where the upper level metal line includes a first portion and a second portion, and a via formed on top of the lower level metal line that interconnects the lower level metal line to the upper level metal line. The via is self-aligned to the lower level metal line along the second direction and self-aligned to the upper level metal line along the first direction. The resulting semiconductor interconnect structure of the present invention results in a technical advantage of eliminating edge placement errors, and thereby any reliability or performance issues caused by edge placement errors, when forming a via on top of a lower level metal line as compared to conventional semiconductor interconnect structures.

In an embodiment, the first direction from which the lower level metal line extends along is perpendicular to the second direction from which the upper level metal line extends along.

In an embodiment, the first portion of the upper level metal line is formed from a subtractive manufacturing process, and the second portion of the upper level metal line is formed from an additive manufacturing process. This results in a technical advantage of the via formed on top of the lower level metal line being self-aligned to the second portion of the upper level metal line along the first direction.

In an embodiment, the first portion and the second portion of the upper level metal line are comprised of different conductive metal materials. This results in a technical effect of the first and second portions of the upper level metal line having different degrees of electrical conductivity.

In an embodiment, the first portion and the second portion of the upper level metal line are comprised of the same materials. This results in a technical effect of the first and second portions of the upper level metal line having the same degree of electrical conductivity.

In an embodiment, the first portion of the upper level metal line is comprised of a conductive metal material selected from the group consisting of aluminum (Al), ruthenium (Ru), rhodium (Rh), iridium (Ir), tungsten (W), molybdenum (Mo), and nickel (Ni). This results in a technical effect of being able to form the first portion of the upper level metal line using a subtractive manufacturing process.

In an embodiment, a bottom surface of the via is self-aligned to a top surface of the lower level metal line along the second direction. This results in a technical advantage of reducing and/or eliminating via resistance and shorting concerns caused by edge placement errors when forming a via on top of a lower level metal line.

In an embodiment, a top surface of the via is self-aligned to a bottom surface of the second portion of the upper level metal line along the first direction. This results in a technical advantage of reducing and/or eliminating via resistance and shorting concerns caused by edge placement errors when forming an upper level metal line on top of a via.

In an embodiment, the bottom surface of the second portion of the upper level metal line overhangs the top surface of the via along the second direction.

In an embodiment, the top surface of the second portion of the upper level metal line is located above the top surface of the first portion of the upper level metal line.

In an embodiment, the top surface of the second portion of the upper level metal line is substantially coplanar with the top surface of the first portion of the upper level metal line.

In an embodiment, the top surface of the second portion of the upper level metal line is located below the top surface of the first portion of the upper level metal line.

In an embodiment, the bottom surface of the second portion of the upper level metal line is substantially coplanar with the bottom surface of the first portion of the upper level metal line.

In an embodiment, the bottom surface of the second portion of the upper level metal line is located below the bottom surface of the first portion of the upper level metal line.

According to another embodiment of the present invention, a method of forming a semiconductor interconnect structure is provided.

The method includes forming a first hard mask on top of a first metal layer, and etching, using the first hard mask, the first metal layer to form a lower level metal line extending along a first direction. This results in a technical effect of the first hard mask being self-aligned to the lower level metal line.

The method further includes forming a first insulating layer, such that a top surface of the first insulating layer is coplanar with a top surface of the first hard mask. This results in a technical effect of the first hard mask and the lower level metal line, which are formed from inorganic materials, being insulated by an organic material.

The method further includes forming a second hard mask on top of a second metal layer, and etching, using the second hard mask, the second metal layer to form an upper level metal line extending along a second direction. This results in technical effect of the second hard mask being self-aligned to the upper level metal line.

The method further includes forming a second insulating layer, such that a top surface of the second insulating layer is coplanar with a top surface of the second hard mask. This results in a technical effect of the second hard mask and the upper level metal line, which are formed from inorganic materials, being insulated by an organic material.

The method further includes forming a soft mask having a first opening that exposes a portion of the second hard mask located on top of the upper level metal line. This results in a technical effect of the exposed portion of the second hard mask, formed from an inorganic material, to be selectively etched relative to the organic materials of the soft mask and second insulating layer. In some embodiments, the first opening is formed such that the edges of the opening extend beyond the edges of the second hard mask along the first direction. This also results in a technical advantage of eliminating overlay issues when patterning the soft mask material of the soft mask during the lithography process. Because the exposed portion of the second hard mask can be selectively etched, the patterned photoresist material used to create the opening in the soft mask need not be perfectly aligned to the underlying portion of the second hard mask. Rather, the patterned photoresist material used to create the opening formed in the soft mask may be relaxed along the first direction to ensure that the removal of the portion of the second hard mask located on top of the upper level metal results in the top surface of the underlying upper level metal line being completely exposed along the first direction.

The method further includes selectively etching the exposed portion of the second hard mask to form a second opening that exposes a portion of the upper level metal line, where the second opening is self-aligned to the upper level metal line along the first direction. This results in a technical effect of only removing the hard mask material. This also results in a technical advantage of the second opening being self-aligned to the upper level metal line in at least one direction.

The method further includes selectively etching the exposed portion of the upper level metal line to form a trench opening in the upper metal line that exposes a portion of the first hard mask located on top of the lower level metal line. This results in a technical effect of only removing the conductive metal material from the upper level metal line.

The method further includes selectively etching the exposed portion of the first hard mask to form a via opening that exposes a portion of the lower level metal line, where the via opening is self-aligned to the lower level metal line along the second direction. This results in a technical effect of only removing the hard mask material. This also results in a technical advantage of the via opening being self-aligned to the lower level metal line in at least one direction.

The method further includes filling the via opening and the trench opening formed within the upper level metal line with a conductive metal material. Filling the via opening with the conductive metal material results in a technical effect and/or advantage of the formation of a via on top of, and self-aligned to, the lower level metal line along the second direction. Filling the trench opening formed within the upper level metal line with the conductive material results in a technical effect of the formation of an upper level metal line replacement section that is integrated with the upper level metal line. This also results in a technical effect and/or advantage of the via being self-aligned to the upper level metal line replacement section along the first direction.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

As used herein, terms such as “depositing,” “forming,” and the like may refer to the disposition of layers, or portions of materials, in accordance with a given embodiment. Such processes may or may not be different than those used in the standard practice of the art of microcooler device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, micromachining, microetching, wet and/or dry etching processes, plasma etching processes, or any of the known etching processes in which material is removed.

As used herein, the term “fully aligned via” may refer to a via that is self-aligned to both a lower level metal line and an upper level metal line.

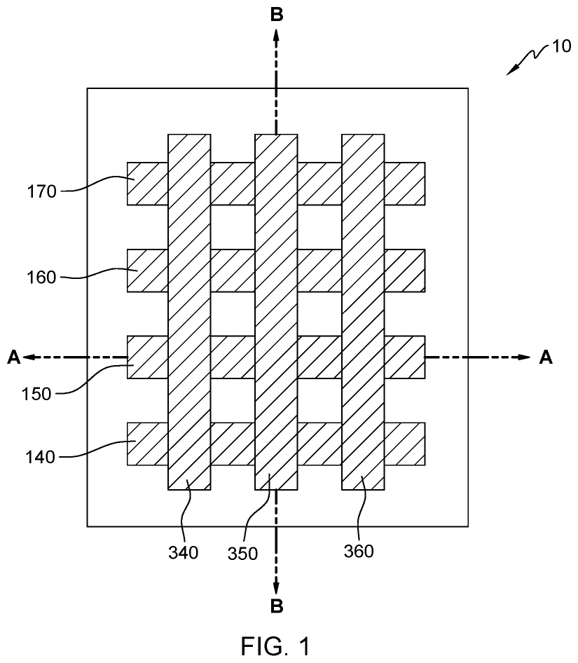

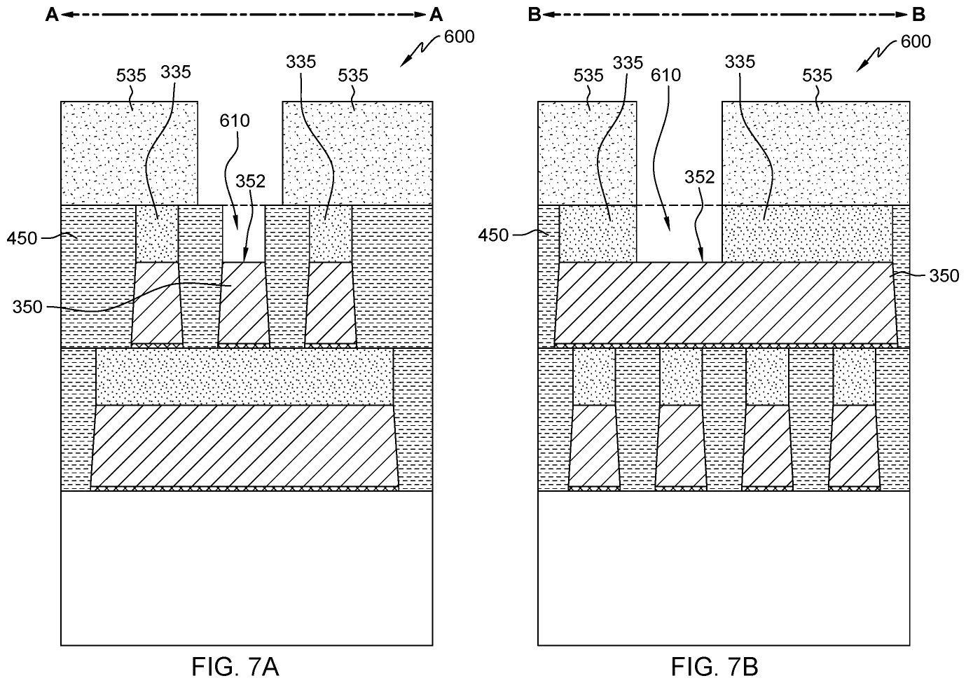

The present invention will now be described in detail with reference to the Figures. FIGS. 1, and 2A, 2B-11A, 11B include various views depicting illustrative steps of a method for manufacturing semiconductor interconnect structures and the resulting semiconductor interconnect structures according to select embodiments of the present invention. One having ordinary skill in the art will appreciate that there are many options available for the formation of the structures described herein and that the following discussion does not limit embodiments to only the techniques described herein. It should be noted that the use of dotted lines, for example, as depicted in FIGS. 7A, 7B-11A, 11B, are for reference purposes only (e.g., to distinguish one element from another), and are not to be construed as structural elements.

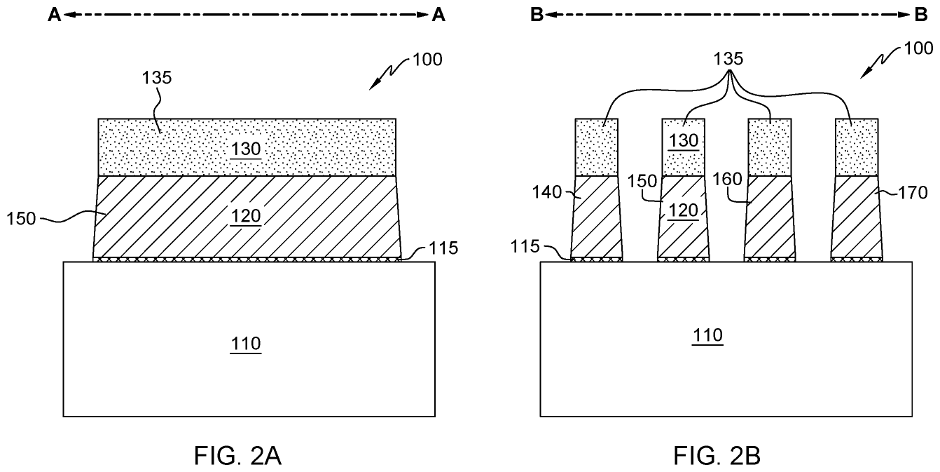

FIG. 1 depicts a simple diagram of a top view of a semiconductor structure, generally designated 10, in accordance with at least one embodiment of the present invention. For simplicity and ease of understanding, FIG. 1 omits some elements and/or layers so as to not obscure the figure. FIG. 1 is intended for reference purposes only and illustrates a top-down view of locations and relative orientations of the lower level metal lines 140, 150, 160, 170 and upper level metal lines 340, 350, 360 formed during subsequent processing steps in accordance with FIGS. 2A, 2B-11A, 11B. As depicted in FIG. 1, the lower level metal lines 140, 150, 160, 170 extend along a first direction (i.e., extend along the direction of Line A) and the upper level metal lines 340, 350, 360 extend along a second direction (i.e., extend along the direction of Line B). FIGS. 2A-10A depict cross-sectional views of semiconductor structure 10 of FIG. 1 taken along line A and FIGS. 2B-10B depict cross-sectional views of semiconductor structure 10 of FIG. 1 taken along line B.

FIGS. 2A, 2B illustrate cross-sectional views of an initial semiconductor structure, generally designated 100, in accordance with at least one embodiment of the present invention. Referring to the cross-sectional views of FIGS. 1A, 1B taken along corresponding lines A, B of FIG. 1, an optional barrier layer 115, a first metal layer 120, and first hard mask layer 130 are formed on top of a substrate 110, the first hard mask layer 130 is patterned to form a first hard mask 135, and using the first hard mask 135, the first metal layer 120 is etched to form lower level metal lines 140, 150, 160, 170 of a lower metal level (e.g., Mx-1). The etching of the first metal layer 120 to form the lower level metal lines 140, 150, 160, and 170 may generally be referred to herein as a subtractive manufacturing process.

In some embodiments, and as depicted in FIGS. 2A, 2B, substrate 110 is a bulk semiconductor wafer, such as a bulk silicon (Si), bulk germanium (Ge), bulk silicon germanium (SiGe) and/or bulk III-V semiconductor wafer. Alternatively, in other embodiments, substrate 110 is a semiconductor-on-insulator (SOI) wafer. A SOI wafter includes a SOI layer separated from a substrate by a buried insulator. When the buried insulator is an oxide, it is referred to herein as a buried oxide or BOX. The SOI layer can include any suitable semiconductor, such as Si, Ge, SiGe, and/or a III-V semiconductor.

In some embodiments, substrate 110 may be part of a front-end-of-the-line (FEOL) structure. A FEOL structure is typically present beneath the lowest level of the multilayered interconnect structure and includes a semiconductor substrate having one or more semiconductor devices such as, for example, transistors, capacitors, resistors, and etc. located thereon. In other embodiments, substrate 110 may include one or more interconnect levels of a multilayered interconnect structure, such as a back-end-of-the-line (BEOL) structure. A BEOL structure is typically where the individual semiconductor devices in the FEOL structure are interconnected with one another. In such embodiments, each interconnect level (i.e., metal level) may include one or more electrically conductive structures embedded in an interconnect dielectric material.

In assembly of semiconductor structure 100, a metal barrier material is deposited onto the top surface of substrate 100 to form the optional barrier layer 115, a conductive metal material is deposited onto the optional barrier layer 115 to form the first metal layer 120, and a hard mask material is deposited onto conductive metal layer 120 to form the first hard mask layer 130. The optional barrier layer 115, first metal layer 120, and first hard mask layer 130 may be formed by depositing the metal barrier material, conductive metal material, and hard mask material using known techniques including, but not limited to, chemical vapor deposition (CVD), plasma enhanced chemical vapor deposition (PECVD), atomic layer deposition (ALD), physical vapor deposition (PVD), sputtering, chemical solution deposition or plating.

The optional barrier layer 115 may include one or more thin layers of material such as, for example, tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN) manganese (Mn), manganese nitride (MnN) or other barrier materials (or combinations of barrier materials) such as RuTaN, Ta/TaN, CoWP, NiMoP, or NiMoB which are suitable for the given application. The thin metal barrier serves as a barrier diffusion layer and adhesion layer. The thickness of the optional barrier layer 115 may vary depending on the deposition process used, as well as the material employed. In some embodiments, the optional barrier layer 115 may have a thickness from 1 nm to 5 nm. However, other thicknesses that are less than 1 nm, or greater than 5 nm can also be employed in embodiments of the present invention.

The first metal layer 120 may be composed of a metal or metal alloy suitable for subtractive etching, including, but not limited to, aluminum (Al), ruthenium (Ru), rhodium (Rh), iridium (Ir), tungsten (W), molybdenum (Mo), nickel (Ni), or an alloy thereof. The first hard mask layer 130 may be composed of an inorganic hard mask material including, but not limited to, silicon nitride, titanium nitride, tantalum nitride, or any suitable inorganic metal-containing material.

In an embodiment, the lower level metal lines 140, 150, 160, 170 may be formed as follows. A photoresist material (not depicted) is deposited onto the surface of the first hard mask layer 130. The photoresist material can be applied by any suitable techniques, including, but not limited to, coating or spin-on techniques. A photomask (not depicted) patterned with shapes defining the lower level metal lines 140, 150, 160, 170 to be formed is placed over the photoresist material, and the photomask pattern is transferred to the photoresist material using a lithographic process, which creates recesses in the uncovered regions of the photoresist material. The resulting patterned photoresist material is subsequently used to create the same pattern in the first hard mask layer 130. Dry etch techniques (for example, an anisotropic etch process, such as reactive ion etch) may be employed to selectively remove portions of the first hard mask layer 130 to form the first hard mask 135. After formation of the first hard mask 135, the photoresist material may be stripped from the first hard mask 135 by ashing or other suitable processes. The resulting structure may be subjected to a wet clean.

Using the first hard mask 135, the physically exposed portions of the first metal layer 120 are removed by an anisotropic etching process such as, for example, reactive ion etching (RIE), ion beam etching (IBE), chemical wet etching, or a combination of IBE and chemical wet etching. The etch removes the exposed portions of the first metal layer 120 that are not protected by the first hard mask 135 to form lower level metal lines 140, 150, 160, 170.

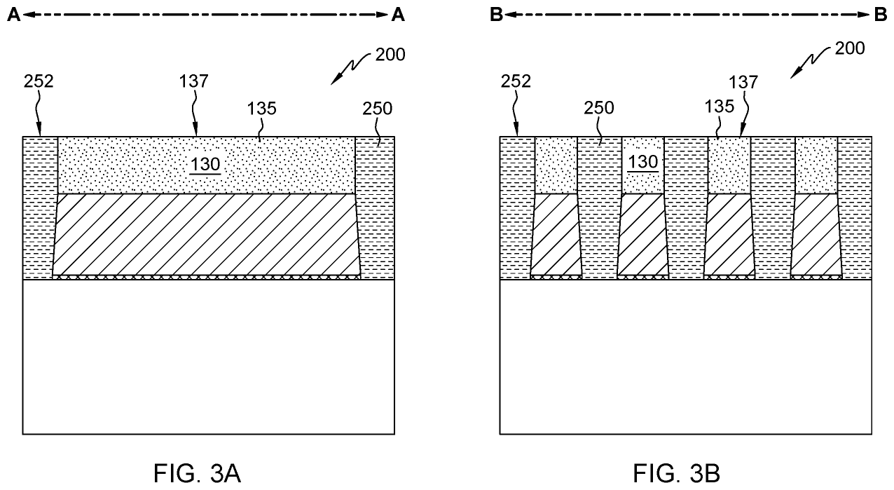

FIGS. 3A, 3B illustrate cross-sectional views of semiconductor structure 100 depicted in FIGS. 2A, 2B after performing subsequent processing steps, generally designated 200, in accordance with at least one embodiment of the present invention. In assembly of semiconductor structure 200, and referring to the cross-sectional views of FIGS. 3A, 3B taken along corresponding lines A, B of FIG. 1, an insulating material is conformally deposited onto the semiconductor structure 200 of Figures A, 2B to form insulating layer 250.

Insulating layer 250 may be formed by depositing an insulating material using known techniques including, but not limited to, chemical vapor deposition (CVD), plasma enhanced chemical vapor deposition (PECVD), atomic layer deposition (ALD), physical vapor deposition (PVD), sputtering, chemical solution deposition, or any other suitable deposition techniques. In an embodiment, insulating layer 250 is an inter-layer dielectric (ILD). Insulating layer 250 may be composed of an inorganic dielectric material or an organic dielectric material. In some embodiments, insulating layer 250 may be porous. In other embodiments, insulating layer 250 may be non-porous. In some embodiments, insulating layer 250 may have a dielectric constant (all dielectric constants mentioned herein are measured relative to a vacuum, unless otherwise stated) that is about 4.0 or less. In an embodiment, insulating layer 250 may have a dielectric constant of 2.8 or less. These dielectrics having a dielectric constant of 2.8 or less generally have a lower parasitic cross talk as compared to dielectric materials whose dielectric constant is greater than 4.0. Examples of suitable dielectric materials that may be employed as insulating layer 250 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, O and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

A planarization process such as, for example, chemical mechanical planarization or polishing (CMP) and/or grinding, may subsequently be performed to remove portions of the insulating layer 250 present above the top surface 137 of the first hard mask 135. The planarization stops when the top surface 252 of the first insulating layer 250 is substantially coplanar with the top surface 137 of the first hard mask 135.

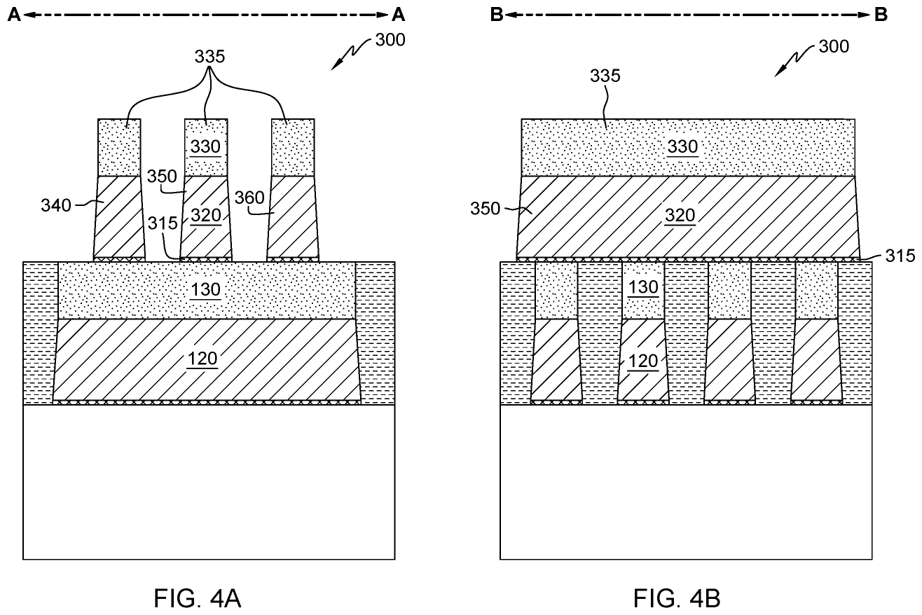

FIGS. 4A, 4B illustrate cross-sectional views of semiconductor structure 200 depicted in FIGS. 3A, 3B after performing subsequent processing steps, generally designated 300, in accordance with at least one embodiment of the present invention. In assembly of semiconductor structure 300, and referring to the cross-sectional views of FIGS. 4A, 4B taken along corresponding lines A, B of FIG. 1, an optional barrier layer 315, a second metal layer 320, and a second hard mask layer 330 are formed on top of semiconductor structure 200 of FIGS. 3A, 3B, the second hard mask layer 330 is patterned to form a second hard mask 335, and using the second hard mask 335, the second metal layer 320 is etched to form upper level metal lines 340, 350, 360 of an upper metal level (e.g., Mx). The etching of the second metal layer 320 to form the lower level metal lines 340, 350, 360 may generally be referred to herein as a subtractive manufacturing process.

In assembly of semiconductor structure 300, a barrier material is deposited onto the top surface of semiconductor structure 200 to form the optional barrier layer 315, a conductive metal material is deposited onto the optional barrier layer 315 to form the second metal layer 320, and a hard mask material is deposited onto the second metal layer 320 to form the second hard mask layer 330. The optional barrier layer 315, second metal layer 320, and second hard mask layer 330 may be formed using the same processes and materials as previously described above with reference to the optional barrier layer 115, the first metal layer 120, and the first hard mask layer of FIGS. 2A, 2B. In some embodiments, and as depicted in FIGS. 4A, 4B, the first metal layer 120 and the second metal layer 320 are formed from the same material(s). However, in other embodiments, the first metal layer 120 and the second metal layer 320 may be formed from different materials.

The second hard mask 330 and the upper level metal lines 340, 350, 360 may be formed using the same processes as described above with respect to the formation of the first hard mask 135 and the lower level lines 140, 150, 160, and 170 of FIGS. 2A, 2B. For example, the second hard mask 335, which acts as an etch mask, is formed such that the portions of the underlying optional barrier layer 315 and the second metal layer 320 corresponding to upper level metal lines 340, 350, 360 to be formed are protected by the second patterned hard mask 335, while the remaining portions of the underlying optional barrier layer 315 and second metal layer 320 are left exposed. During patterning of the optional barrier layer 315 and the second metal layer 320 using the second hard mask 335, the physically exposed portions of the optional barrier layer 315 and the second metal layer 320 are removed by an anisotropic etching process such as, for example, reactive ion etching (RIE), ion beam etching (IBE), chemical wet etching, or a combination of IBE and chemical wet etching to form upper level metal lines 340, 350, 360.

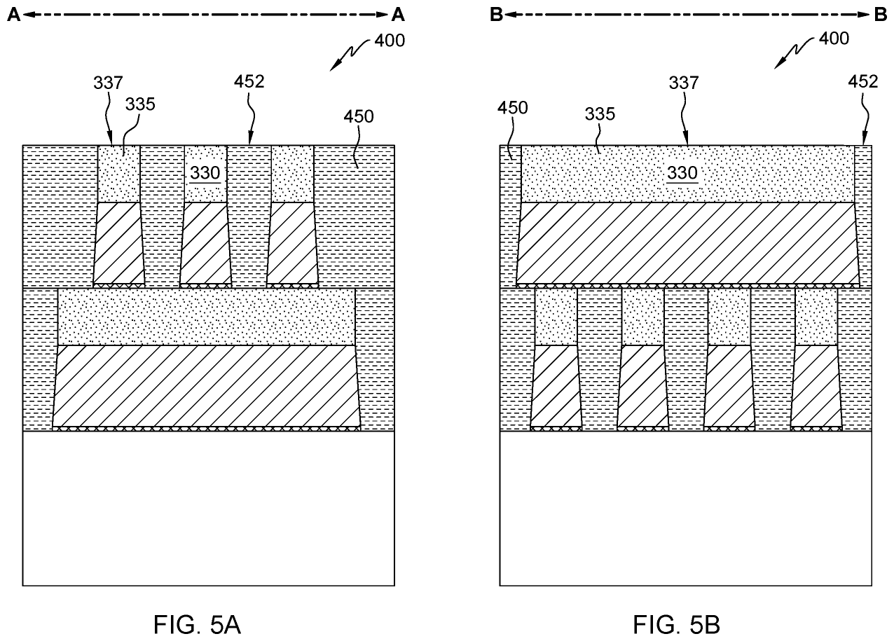

FIGS. 5A, 5B illustrate cross-sectional views of semiconductor structure 300 depicted in FIGS. 4A, 4B after performing subsequent processing steps, generally designated 400, in accordance with at least embodiment of the present invention. In assembly of semiconductor structure 400, and referring to the cross-sectional views of FIGS. 5A, 5B taken along corresponding lines A, B of FIG. 1, an insulating material is conformally deposited onto the semiconductor structure 300 of FIGS. 4A, 4B to form a second insulating layer 450.

The second insulating layer 450 may be formed using the same materials and processes as described above with respect to the formation of the first insulating layer 250 of FIGS. 3A, 3B. A planarization process such as, for example, chemical mechanical planarization or polishing (CMP) and/or grinding, may subsequently be performed to remove portions of the second insulating layer 450 present above the top surface 337 of the second hard mask 335. The planarization stops when the top surface 452 of the second insulating layer 450 is substantially coplanar with the top surface 337 of the second hard mask 335.

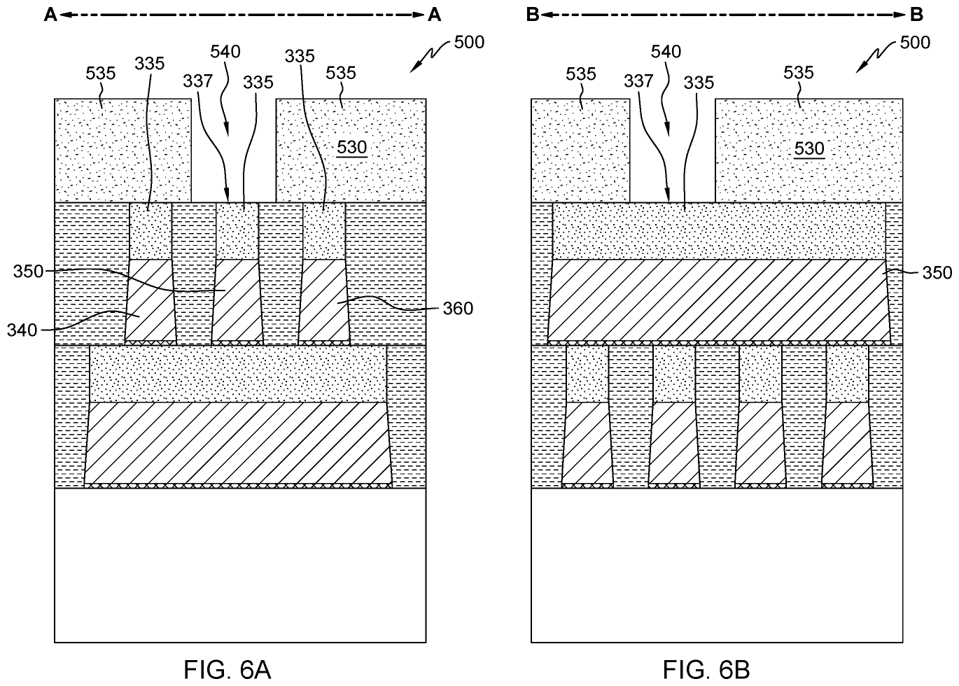

FIGS. 6A, 6B illustrate cross-sectional views of semiconductor structure 400 depicted in FIGS. 5A, 6B after performing subsequent processing steps, generally designated 500, in accordance with at least one embodiment of the present invention. In assembly of semiconductor structure 500, and referring to the cross-sectional views of FIGS. 6A, 6B taken along corresponding lines A, B of FIG. 1, a soft mask layer 530 is formed on top of semiconductor structure 400, followed by the patterning of the soft mask layer 530 to form soft mask 535.

In assembly of semiconductor structure 500, the soft mask layer 530 is formed by depositing an organic soft mask material (e.g., carbon, hydrogen, oxygen, and optionally nitrogen, fluorine, and silicon) onto the top surface of semiconductor structure 400. In some embodiments, the soft mask layer 530 is an organic planarization layer (OPL). The soft mask layer 530 is subsequently patterned to form a soft mask 535 using the same processes as described above with reference to the formation of the first hard mask 135 of FIGS. 2A, 2B. The resulting soft mask 535, which acts as a selective etch mask, is formed such that the opening 540 exposes the top surface 337 of a portion of the second hard mask 335 formed on top of upper metal line 350, while the portions of the second hard mask 335 formed on top of the upper metal lines 340, 360 remain protected by the soft mask 535.

It should be noted that the size of the opening 540 technically need only be such that the edges of the opening 540 are aligned to the edges of the second hard mask 335 along the direction of line A. However, to take into account the potential for any overlay errors when patterning the soft mask layer 530 during the lithography process, the size of the opening 540 along the direction of line A is relaxed. In other words, the opening 540 is formed such that the edges of the opening 540 extend beyond the edges of the second patterned hard mask 335 along the direction of line A. It should be appreciated that there is no penalty for doing so, since the exposed portion of the second hard mask 335, formed from an inorganic material, can be selectively etched relative to the second insulating layer 450 and the soft mask layer 530, which are formed from organic materials. Accordingly, even if the opening 540 is relaxed such that a portion of the second insulating layer 450 adjacent to the second hard mask 335 is also exposed, only the material of the second hard mask 335 will be removed as a result of the etch selectively. Moreover, relaxing the opening 540 ensures that the subsequent removal of the portion of the second hard mask 335 results in the top surface of the underlying upper level metal line 350 being completely exposed along the direction of line A.

FIGS. 7A, 7B illustrate cross-sectional views of semiconductor structure 500 depicted in FIGS. 6A, 6B after performing subsequent processing steps, generally designated 600, in accordance with at least one embodiment of the present invention. In assembly of semiconductor structure 600, and referring to the cross-sectional views of FIGS. 7A, 7B taken along corresponding lines A, B of FIG. 1, the hard mask material corresponding to the exposed portion of the second hard mask 335 formed on top of upper level metal line 350 is selectively removed.

The hard mask material of the exposed portion of the second hard mask 335 may be selectively removed over the materials of the soft mask 535 and the second insulating layer 450 using, for example, reactive ion etching. However, it should be appreciated that any known etching processes and types of etchants that are selective to the material of the second hard mask 335 over the materials of the soft mask 535 and the second insulating layer 450 can be used to selectively remove the exposed portion of the second hard mask 335 located on top of upper level metal line 350. The selective removal of the exposed portion of the second hard mask 335 located on top of upper level metal line 350 results in the formation of a second opening 610 that exposes the top surface 352 of a portion of the upper level metal line 350.

It should be appreciated that since the second hard mask 335 is self-aligned to the upper level metal line 350 along the direction of line A (as depicted in FIG. 6A), the second opening 610 formed as a result of the removal of the exposed portion of the second hard mask 335 is therefore also self-aligned to the upper level metal line 350 along the direction of line A.

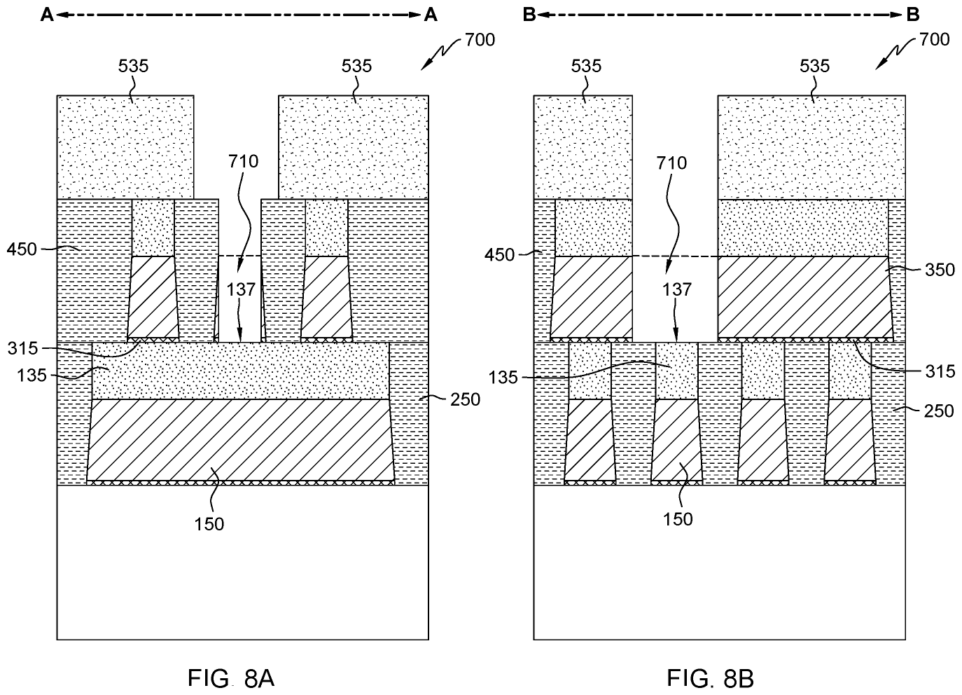

FIGS. 8A, 8B illustrate cross-sectional views of semiconductor structure 600 depicted in FIGS. 7A, 7B after performing subsequent processing steps, generally designated 700, in accordance with at least one embodiment of the present invention. In assembly of semiconductor structure 700, and referring to the cross-sectional views of FIGS. 8A, 8B taken along corresponding lines A, B of FIG. 1, the conductive metal materials corresponding to the exposed portion of the upper level metal line 350 and the portion of the optional barrier layer 315 located thereunder, are selectively removed to form a trench opening 710 in the upper level metal line 350. The conductive metal materials of the upper level metal line 350 and optional barrier layer 315 may be selectively removed over the materials of the soft mask 535, second insulating layer 450, and first insulating layer 250 using, for example, reactive ion etching. However, it should be appreciated that any known etching processes and types of etchants that are selective to the materials of the upper metal line 350 and the optional barrier layer 315 over the materials of the soft mask 535, second insulating layer 450, and first insulating layer 250 can be used. The selective removal of the exposed portion of the upper level metal line 350 and the optional barrier layer 315 located underneath results in the formation of the trench opening 710 in the upper level metal line 350 that exposes the top surface 137 of the first hard mask 135 formed on top of the lower level metal line 150.

It should be noted that although the size of the trench opening 710 along the direction of line B is relaxed (i.e., the trench opening 710 is formed such that the edges of the trench opening 710 extend beyond the edges of the exposed portion of the first hard mask 135 along the direction of line B), there is no penalty for doing so. This stems from the fact that the exposed portion of the first hard mask 135, formed from an inorganic material, can be selectively etched relative to the first insulating layer 250, which is formed from organic materials. Accordingly, even if the trench opening 710 is relaxed such that a portion of the second insulating layer 250 adjacent to the first hard mask 135 is also exposed, only the material of the first hard mask 135 will be removed as a result of the etch selectively.

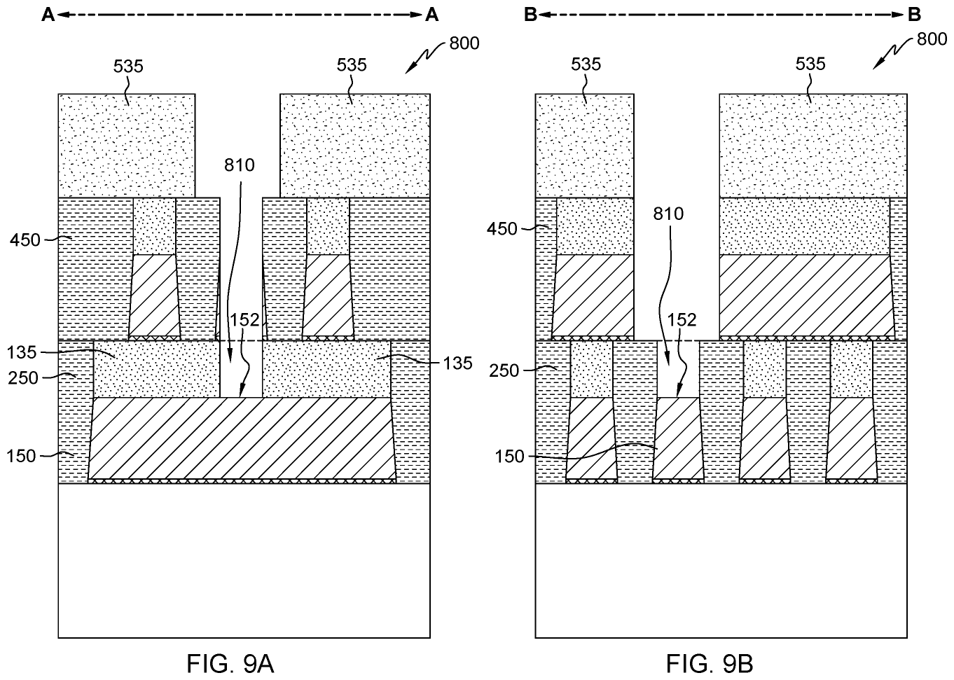

FIGS. 9A-9B illustrate cross-sectional views of semiconductor structure 700 depicted in FIGS. 8A, 8B after performing subsequent processing steps, generally designated 800, in accordance with at least one embodiment of the present invention. In assembly of semiconductor structure 800, and referring to the cross-sectional views of FIGS. 8A, 8B taken along corresponding lines A, B of FIG. 1, the hard mask material corresponding to the exposed portion of the hard mask 135 formed on top of the lower level metal line 150 is selectively removed to form a via opening 810 that is self-aligned to the top surface 152 of the lower level metal line 150. The hard mask material of the first hard mask 135 may be selectively removed over the materials of the soft mask 535, second insulating layer 450, and first insulating layer 250 using, for example, reactive ion etching. However, it should be appreciated that any known etching processes and types of etchants that are selective to the material of the first hard mask 135 over the materials of the soft mask 535, second insulating layer 450, and first insulating layer 250 can be used to selectively remove the exposed portion of the first hard mask 135. The removal of the exposed portion of the first hard mask 135 formed on top of the lower level metal line 150 results in the formation of the via opening 810 that exposes the top surface 152 of a portion of the lower level metal line 150.

It should be appreciated that since the first hard mask 135 is self-aligned to the lower level metal line 150 along the direction of line A (as depicted in FIG. 9A), the via opening 810 formed as a result of the removal of the exposed portion of the first hard mask 135 is therefore also self-aligned to the lower level metal line 150 along the direction of line A.

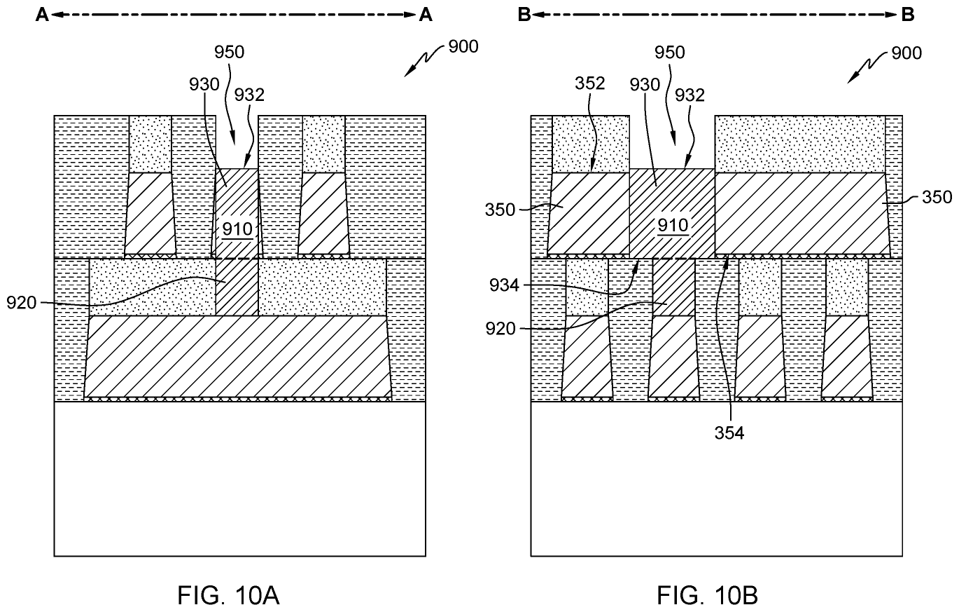

FIGS. 10A, 10B illustrate cross-sectional views of semiconductor structure 800 depicted in FIGS. 9A, 9B after performing subsequent processing steps, generally designated 900, in accordance with at least one embodiment of the present invention. In assembly of semiconductor structure 900, and referring to the cross-sectional views of FIGS. 10A, 10B taken along corresponding lines A, B of FIG. 1, the soft mask 535 (depicted in FIGS. 9A, 9B) is removed (e.g., via an OPL plasma strip), followed by the filling of the via opening 810 (depicted in FIGS. 9A, 9B) and the trench opening 710 (depicted in FIGS. 9A, 9B) with a conductive metal material 910 to form a via 920, and an upper level metal line replacement section 930 integrated with the upper level metal line 350. The filling of the via opening 810 and trench opening 710 with the conductive metal material 910 to form the via 920 and upper level metal line replacement section 930 may generally be referred to herein as an additive manufacturing process.

The Via 920 and upper level metal line replacement section 930 may be formed by depositing the conductive metal material 910 (e.g., via area selective ALD, area selective CVD, plating, electroplating, or any other suitable deposition techniques) within the via opening 810 (depicted in FIGS. 9A, 9B) and the trench opening 710 (depicted in FIGS. 9A, 9B), such that the deposition of the conductive metal material 910 is limited to the via opening 810 and the trench opening 710. The conductive metal material 910 used to form the via 920 and upper level metal line replacement section 930 may be a metal or metal alloy including, but not limited to, copper (Cu), aluminum (Al), ruthenium (Ru), rhodium (Rh), iridium (Ir), tungsten (W), molybdenum (Mo), nickel (Ni), or an alloy thereof, such as, for example, a Cu—Al alloy. In some embodiments, the via 920 and upper level metal line replacement section 930 are formed from the same material(s) as the upper level metal line 350. In other embodiments, the via 920 and upper level metal line replacement section 930 are formed from a different material(s) than the upper level metal line 350.

In some embodiments, and as depicted in FIGS. 10A, 10B, the top surface 932 of the upper level metal line replacement section 930 is located above the top surface 352 of the upper level metal line 350, and the bottom surface 934 of the upper level metal line replacement section 920 is located below the bottom surface 354 of the upper level metal line 350. However, in other embodiments, the top surface 932 of the upper level metal line replacement section 930 may be substantially coplanar with or located below the top surface 352 of upper level metal line 350. Similarly, in embodiments where the optional barrier layer 315 is not included, the bottom surface 934 of the upper level metal line replacement section 930 may be substantially coplanar with the bottom surface of the upper level metal line 350.

As further depicted in FIG. 10A, the bottom surface 934 of the upper level metal line replacement section 930 overhangs the top surface of the via 920 along the second direction. The via 920 is self-aligned to the upper level metal line replacement section 930 integrated with the upper level metal line 350 along the direction of line A. Similarly, and as depicted in FIG. 10B, the via 920 is also self-aligned to the lower level metal line 150 along the direction of line B. In other words, the via 920 is self-aligned to the lower level metal line 150 along a first direction, and self-aligned to the upper level metal line 350 a long a second direction. In some embodiments, the first direction extending along line A is perpendicular to the second direction extending along line B.

As used herein, the portion of the upper level metal line 350 formed using a subtractive manufacturing process as described above with reference to FIGS. 2A, 2B shall be synonymous with the term “a first portion of the upper level metal line”, and the upper level metal line replacement section 930 formed using an additive manufacturing process as described above with reference to FIGS. 10A, 10B shall be synonymous with the term “a second portion of the upper level metal line.”

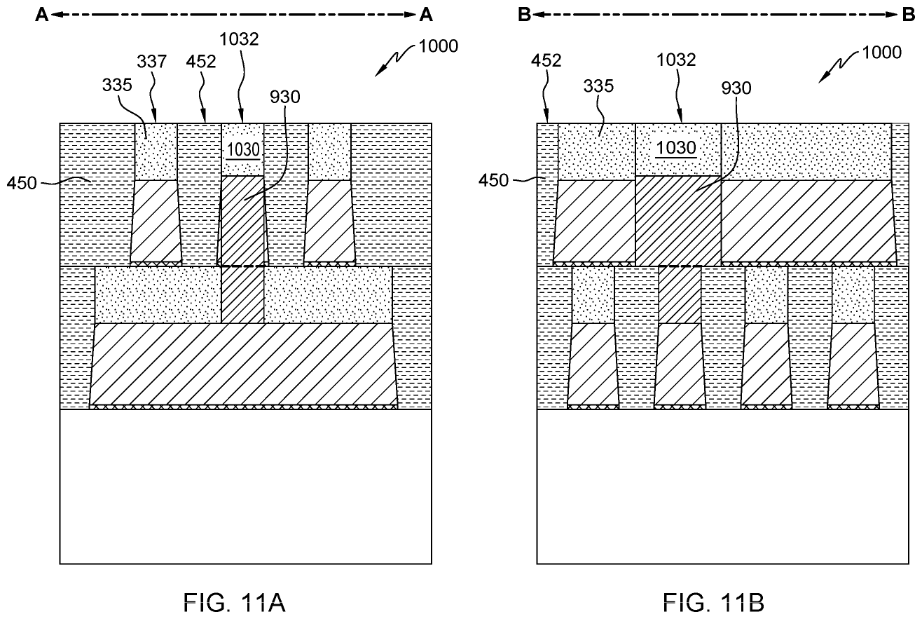

FIGS. 11A, 11B illustrate cross-sectional views of semiconductor structure 900 depicted in FIGS. 10A, 10B after performing subsequent processing steps, generally designated 1000, in accordance with at least one embodiment of the present invention. In assembly of semiconductor structure 1000, and referring to the cross-sectional views of FIGS. 11A, 11B taken along corresponding lines A, B of FIG. 1, the opening 950 (depicted in FIGS. 10A, 10B) in the second hard mask 335 located above the upper level metal line replacement portion 930 integrated with the upper level metal line 350 is filled with a hard mask material 1030. A planarization process such as, for example, chemical mechanical planarization or polishing (CMP) and/or grinding, may subsequently be performed to remove portions of the hard mask material 1030 present above the top surfaces 337, 452 of the second hard mask 335 and the second insulating layer 450. The planarization stops when the top surface 1032 of the hard mask material 1030 is substantially coplanar with the top surfaces 337, 452 of the second hard mask 335 and the second insulating layer 450.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure is not limited to specific described embodiments. Instead, any combination of the features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages discussed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

While the foregoing is directed to embodiments of the present invention, other and further embodiments of the invention may be devised without departing from the basic scope thereof, and the scope thereof is determined by the claims that follow.

What is claimed is:

1. A semiconductor interconnect structure, comprising:
a lower level metal line extending along a first direction;
an upper level metal line extending along a second direction, wherein the upper level metal line includes a first portion and a second portion; and
a via formed on top of the lower level metal line and interconnecting the lower level metal line to the upper level metal line, wherein the via is self-aligned to the lower level metal line along the second direction and self-aligned to the upper level metal line along the first direction.

2. The semiconductor interconnect structure of claim 1, wherein the first direction from which the lower level metal line extends along is perpendicular to the second direction from which the upper level metal line extends along.

3. The semiconductor interconnect structure of claim 1, wherein:
the first portion of the upper level metal line is formed from a subtractive manufacturing process; and
the second portion of the upper level metal line is formed form an additive manufacturing process.

4. The semiconductor interconnect structure of claim 1, wherein the first portion and the second portion of the upper level metal line are comprised of different conductive metal materials.

5. The semiconductor interconnect structure of claim 1, wherein the first portion and the second portion of the upper level metal line are comprised of the same materials.

6. The semiconductor interconnect structure of claim 1, wherein:
the first portion of the upper level metal line is comprised of a conductive metal material selected from the group consisting of aluminum (Al), ruthenium (Ru), rhodium (Rh), iridium (Ir), tungsten (W), molybdenum (Mo), and nickel (Ni); and
the second portion of the upper level metal line is comprised of a conductive metal material selected from the group consisting of group consisting of copper (Cu), aluminum (Al), ruthenium (Ru), rhodium (Rh), iridium (Ir), tungsten (W), molybdenum (Mo), and nickel (Ni).

7. The semiconductor interconnect structure of claim 1, wherein a bottom surface of the via is self-aligned to a top surface of the lower level metal line along the second direction.

8. The semiconductor interconnect structure of claim 1, wherein a top surface of the via is self-aligned to a bottom surface of the second portion of the upper level metal line along the first direction.

9. The semiconductor interconnect structure of claim 8, wherein the bottom surface of the second portion of the upper level metal line overhangs the top surface of the via along the second direction.

10. The semiconductor interconnect structure of claim 1, wherein a top surface of the second portion of the upper level metal line is located above a top surface of the first portion of the upper level metal line.

11. The semiconductor interconnect structure of claim 1, wherein a top surface of the second portion of the upper level metal line is substantially coplanar with a top surface of the first portion of the upper level metal line.

12. The semiconductor interconnect structure of claim 1, wherein a top surface of the second portion of the upper level metal line is located below a top surface of the first portion of the upper level metal line.

13. The semiconductor interconnect structure of claim 1, wherein a bottom surface of the second portion of the upper level metal line is substantially coplanar with a bottom surface of the first portion of the upper level metal line.

14. The semiconductor interconnect structure of claim 1, wherein a bottom surface of the second portion of the upper level metal line is located below a bottom surface of the first portion of the upper level metal line.

15. A method of forming a semiconductor interconnect structure:
forming a first hard mask on top of a first metal layer;
etching, using the first hard mask, the first metal layer to form a lower level metal line extending along a first direction;
forming a first insulating layer, such that a top surface of the first insulating layer is coplanar with a top surface of the first hard mask;
forming a second metal layer and a second hard mask on top of the second metal layer;
etching, using the second hard mask, the second conductive metal layer to form an upper level metal line extending along a second direction;
forming a second insulating layer, such that a top surface of the second insulating layer is coplanar with a top surface of the second hard mask;
forming a soft mask having a first opening that exposes a portion of the second hard mask located on top of the upper level metal line;
selectively etching the exposed portion of the second hard mask to form a second opening that exposes a portion of the upper level metal line, wherein the second opening is self-aligned to the upper level metal line along the first direction;
selectively etching the exposed portion of the upper level metal line to form a trench opening in the upper metal line that exposes a portion of the first hard mask located on top of the lower level metal line;
selectively etching the exposed portion of the first hard mask to form a via opening that exposes a portion of the lower level metal line, wherein the via opening is self-aligned to the lower level metal line along the second direction;
filling the via opening and the trench opening formed within the upper level metal line with a conductive metal material.

16. The method of claim 15, wherein filling the via opening with the conductive metal material results in the formation of a via on top of, and self-aligned to, the lower level metal line along the second direction.

17. The method of claim 16, wherein filling the trench opening formed within the upper level metal line with the conductive metal material results in the formation of an upper level metal line replacement section that is integrated with the upper level metal line, wherein the via is self-aligned to the upper level metal line replacement section along the first direction.

18. The method of claim 17, wherein the upper level metal line and the upper level metal line replacement section integrated with the upper level metal line are comprised of different conductive metal materials.

19. The method of claim 17, wherein the upper level metal line and the upper level metal line replacement section integrated with the upper level metal line are comprised of the same conductive metal materials.

20. The method of claim 17, wherein the bottom surface of the upper level metal line replacement section overhangs a top surface of the via along the second direction.
